(19) United States
(12) Patent Application Publication
(10) Pub. No.: US 2026/0113869 A1
(43) Pub. Date: Apr. 23, 2026

(54) IMMERSION COOLING JACKET AND METHOD FOR LOCALIZED AND TARGETED COOLING OF ELECTRONIC DEVICES

(71) Applicant: Seagate Technology LLC, Fremont, CA (US)

(72) Inventors: Xiong LIU, Shugart (SG); Barish CHAKRAVARTY, Shugart (SG); YiChao MA, Shugart (SG); LiHong ZHANG, Shugart (SG); Swee Chuan GAN, Shugart (SG); Than Zaw MYINT, Shugart (SG)

(21) Appl. No.: 18/918,362

(22) Filed: Oct. 17, 2024

(51) Int. Cl. H05K 7/20

(52) U.S. Cl. CPC H05K 7/20236; H05K 7/20272

(57) ABSTRACT

Described are cooling jackets, cooling jacket assemblies, and cooling jacket systems for localized and targeted immersion cooling of individual electronic devices. As such, individual devices may be immersed using individual device cooling units that are used to provide targeted cooling to those portions of the device that contribute most to heating. Localized immersion cooling jackets and assemblies may be used to replace current whole-system immersion cooling. For localized and targeted cooling of hard disk drives, cooling jackets may be provided that function to better concentrate the cooling action at the circuit board where the heat generating chips may be located. The cooling jackets may be configured to have interface adaptors to facilitate connecting the devices being cooled to system connectors.

### TECHNICAL FIELD

This disclosure relates to immersion cooling of data storage devices.

### SUMMARY

In accordance with various aspects, the present disclosure describes localized immersion cooling assemblies that include an electronic device inserted into a cooling jacket. The electronic device has a heat source that produces heat primarily in or around a first portion of the electronic device, and the cooling jacket contains an immersion cooling fluid such that the immersion cooling fluid cools at least the first portion of the electronic device, while a second portion of the electronic device remains outside of the cooling jacket. In certain aspects, the electronic device is a hard disk drive.

In certain aspects, the cooling jacket includes one or more positioning features to position and stabilize the electronic device when inserted into the cooling jacket.

In certain aspects, the cooling jacket includes an interface adaptor configured to electrically connect an interface of the electronic device to a system connector located outside of the localized immersion cooling assembly.

In certain aspects, the cooling jacket includes a cover that comprises a fluid inlet nozzle and a fluid outlet nozzle. A fluid inlet pipe may be connected to the fluid inlet nozzle, the fluid inlet pipe having an exit end positioned in an interior of the cooling jacket at a location at or near the heat source of the electronic device.

In certain aspects, the immersion cooling fluid is a hydrocarbon cooling liquid, and the cooling jacket is made of polycarbonate (PC), polyoxymethylene (POM), polyamide (PA), or high-density polyethylene (HDPE). In certain aspects, the immersion cooling fluid is a fluorinated cooling liquid, and the cooling jacket is made of polyvinyl chloride (PVC), silicone, styrene-ethylene-butadiene-styrene, thermoplastic olefin, thermoplastic polyurethane, polyether block amide, or epoxy resin.

In certain aspects, the cooling jacket includes a seal configured to substantially enclose the cooling fluid within the cooling jacket when the electronic device is inserted into the cooling jacket. For use with hydrocarbon cooling liquids, the seal may be made of hexafluoropropylene (HFP), vinylidene fluoride (VDF), tetrafluoroethylene (TFE), or fluorinated vinyl ether (FVE). For use with fluorinated cooling liquids, the seal may be made of silicone, natural rubber, polyurethane, polybutadiene, or neoprene.

In accordance with various aspects, the present disclosure describes immersion cooling jackets that include a jacket body configured to contain an immersion cooling fluid and further configured for insertion of a single electronic device through a top opening of the jacket body such that when the single electronic device is fully inserted into the jacket body a first portion of the single electronic device resides in the jacket body and a second portion of the single electronic device remains outside the jacket body. The immersion cooling jackets further include a jacket cover configured to cover the top opening of the jacket body when the single electronic device is inserted into the jacket body, and a jacket seal configured to form a seal between the jacket cover and the single electronic device.

In certain aspects, the jacket may include an interface adaptor configured to electrically connect an interface of the single electronic device to a system connector located outside of the immersion cooling jacket. When the electronic device is a hard disk drive, the interface adaptor may be configured to connect to a SAS interface or SATA interface.

In certain aspects, the immersion cooling fluid may be a hydrocarbon cooling liquid or a fluorinated cooling liquid.

In certain aspects, the jacket body includes one or more positioning features configured to facilitate proper positioning of the electronic device when the electronic device is inserted into the jacket body.

In certain aspects, the jacket body is formed by injection molding or thermoforming.

In accordance with various aspects, the present disclosure further describes hard disk drive immersion cooling systems that include a JBOD chassis including a plurality of hard disk drive connectors, and one or more localized immersion cooling assemblies. Each of the localized immersion cooling assemblies electrically connect a hard disk drive to one of the plurality of hard disk drive connectors through an interface adaptor provided on an immersion cooling jacket that encloses an immersion cooling fluid around at least a portion of the hard disk drive.

The details of one or more aspects of the disclosure are set forth in the accompanying drawings and the description below. Other features, objects, and advantages of the techniques described in this disclosure will be apparent from the description and drawings, and from the claims.

### BRIEF DESCRIPTION OF THE DRAWINGS

FIG. 1A is a schematic perspective view of a localized and targeted immersion cooling jacket installed on a hard disk drive in accordance with certain aspects of the present disclosure.

FIG. 1B is a schematic perspective view of a localized and targeted immersion cooling jacket installed on a hard disk drive in accordance with certain aspects of the present disclosure.

FIG. 1C is a schematic perspective view showing the bottom of a localized and targeted immersion cooling jacket installed on a hard disk drive in accordance with certain aspects of the present disclosure.

FIG. 2 is a schematic exploded view of a cooling jacket assembly for use with localized and targeted immersion cooling of a hard disk drive in accordance with certain aspects of the present disclosure.

FIGS. 3A-3C are schematic perspective views of a cooling jacket body in accordance with certain aspects of the present disclosure.

FIG. 4 is a schematic representation of an array of localized and targeted immersion cooling assemblies in accordance with certain aspects of the present disclosure.

### DETAILED DESCRIPTION

The present disclosure relates to immersion cooling systems, and in particular to providing for localized and targeted immersion cooling. For example, rather than multiple devices being fully immersed in the same cooling bath, individual devices may be immersed using individual device cooling units, and may have their immersion targeted to include those portions that contribute most to device heating. This may be accomplished by the use of individual device cooling “jackets.” As such, in accordance with various aspects of the present disclosure, localized immersion cooling units may be used to replace current whole-system immersion cooling. For localized and targeted cooling of hard disk drives (HDDs), cooling jackets may be provided that function to better concentrate the cooling action at the circuit board where the heat generating chips (such as SOCs, processors, power devices, and so forth) may be located.

Several disadvantages may be associated with current immersion cooling systems including complicated maintenance procedures, environmental concerns, material compatibility, and so forth. Localized and targeted immersion cooling in accordance with the present disclosure may effectively reduce or minimize such concerns. As such, individual device cooling jackets may be designed for targeted immersion of the portions of individual devices that generate the most heat. For HDD cooling, an HDD may be inserted into a cooling jacket that contains an amount of cooling liquid to achieve targeted immersion cooling at least for the chips and other components located on the HDD circuit board. In accordance with various aspects of the present disclosure, cooling jackets may be designed to include interfaces adaptors. In the case of HDDs, such an interface adapter may allow for connecting the HDD to the server system enclosure (referred to herein as the JBOD, for “just a bunch of disks”). In accordance with aspects of the present disclosure, localized and target immersion cooling can take advantage of the design concepts of current air-cooling enclosures and server racks to thereby reduce the added infrastructure costs normally associated with immersion cooling.

While liquid immersion cooling of electronic devices can offer advantages over other cooling methods such as air cooling, it also has disadvantages that can limit its expansion and application. For example, liquid immersion cooling requires that electronic devices be fully immersed in the cooling liquid along with much of the wiring and cable setups and connections. Various hardware and components included in electronic devices and associated wiring may not be compatible with the cooling liquid, resulting in certain materials corroding, dissolving into the coolant, or absorbing the coolant. As such, components and equipment must be specially designed or modified for compatibility. In addition, once the devices and arrays of devices are immersed in the cooling liquids, accessing the devices for upgrade, replacement, repair, or failure analysis can be very challenging and disruptive. Environmental concerns also come into play given the large volume of cooling liquid needed for full immersion of many devices, particularly when the cooling liquid contains PFAS chemicals or other hazardous substances that may damage the atmosphere.

In accordance with the present disclosure, localized and targeted liquid immersion allows for partial immersion that targets the components most in need of cooling, reduces the challenges and disruptions associated with individual device replacement or maintenance, and greatly reduces the amount of cooling liquid needed. As recognized in the present disclosure, localized and targeted liquid immersion cooling can effectively reduce the usage of expensive and potentially environmentally damaging cooling liquids, can reduce the overall weight and size of immersion cooling systems, can reduce concerns regarding material compatibility (since fewer components are immersed), can facilitate accessibility and easy installation, repair, and removal of devices, and can promote more efficient use of current infrastructure since localized immersion cooling allows for the continued leveraging of conventional air cooling.

Reference will now be made to the drawings, which depict one or more aspects described in this disclosure. However, it will be understood that other aspects not depicted in the drawings fall within the scope of this disclosure. Like numbers used in the figures refer to like components, steps, and the like. However, it will be understood that the use of a reference character to refer to an element in a given figure is not intended to limit the element in another figure labeled with the same reference character. In addition, the use of different reference characters to refer to elements in different figures is not intended to indicate that the differently referenced elements cannot be the same or similar. It will also be appreciated that the drawings are meant to illustrate certain aspects and arrangements of features in a way that contributes to their understanding and are not meant to be scale drawings that accurately represent size or shape of elements.

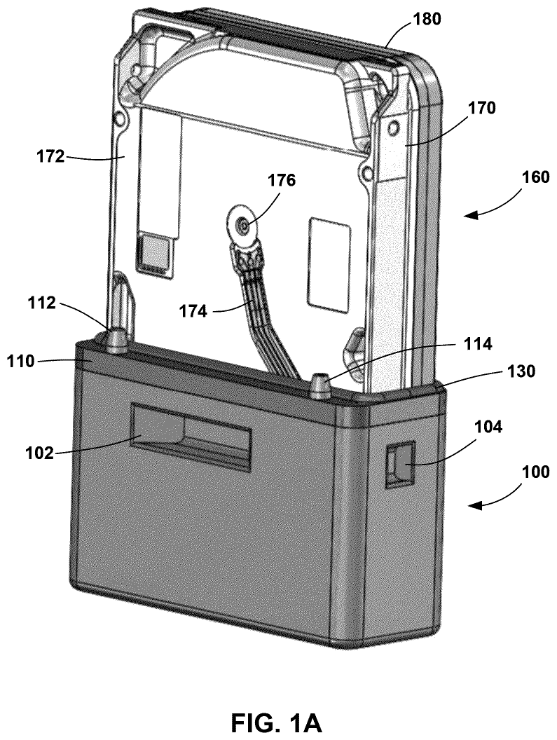

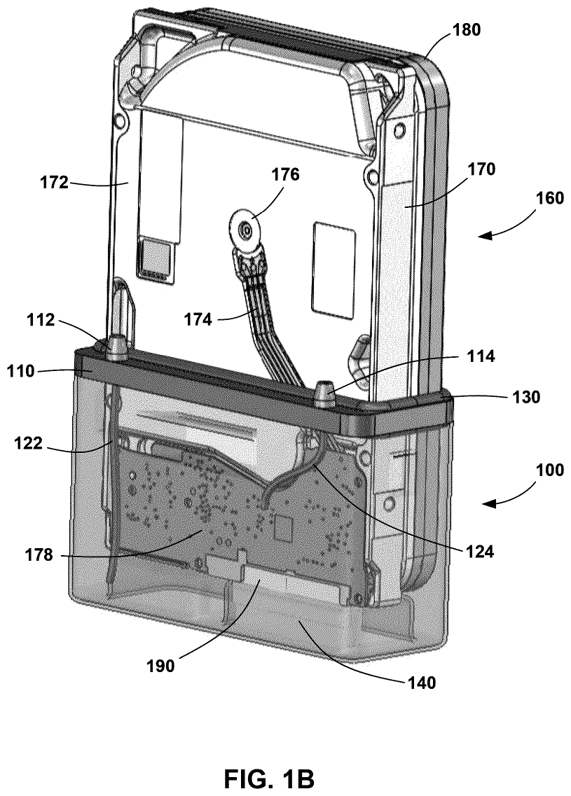

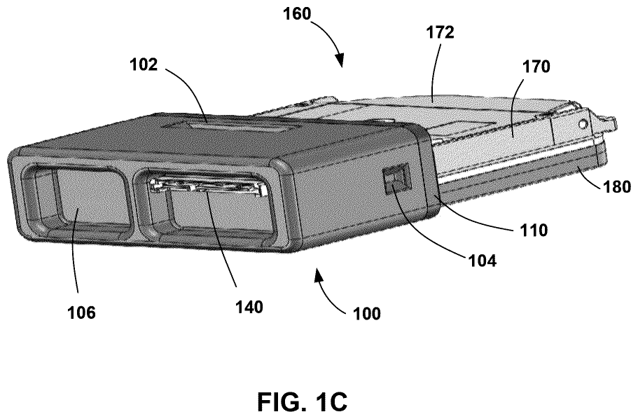

FIG. 1A schematically depicts an example of an electronic device inserted into a liquid cooling jacket 100. In this example, the electronic device is shown to be an HDD 160 whose components that require cooling are located on the lower portion of the HDD 160, thus being amenable to localized and targeted cooling. The perspective view of FIG. 1A primarily shows the back 172 of HDD 160, indicated a spindle motor 176 and a portion of electrical traces 174 being exposed outside of the cooling jacket 100. The enclosure of HDD 160 includes a base 170 attached to a front cover 180, which may be hermetically sealed together, thereby preventing incursion of any cooling liquid into the interior of the HDD 160. The cooling jacket 100 is designed to encompass the portions of HDD 160 that require cooling, to contain a cooling liquid that surrounds the portion of HDD 160 that is inserted into jacket 100, and to electrically connect the HDD 160 to a connector array such as a JBOD chassis (connectors shown in subsequent figures).

A rubber seal 130 may be used to seal the cooling liquid within the coolant jacket 100. The jacket 100 is provided with a cover 110 that is equipped with nozzles 112 and 114 and pipes (shown in subsequent figures) that are configured to channel the flow of the cooling liquid. The cover 110 and seal 130 may be designed such that there is no gap between the coolant jacket 100 and the cover of the HDD 160 upon assembly of the cover 110 and seal 130. Jacket 100 may include device positioning features 102 and 104 that are designed to hold the HDD 160 in place with a desired amount of stability. It will be appreciated that the device positioning features can be any size or shape that facilitates the positioning and holding of the HDD or other device, particularly when those sizes or shapes are easily formed or molded. As one non-limiting example, positioning feature 102 may be formed as two adjacent smaller positioning features rather than a single larger feature.

FIG. 1B shows the same view of HDD 160 inserted into cooling jacket 100, but with cooling jacket 100 made semi-transparent to show the internal components. In addition to what was described with respect to FIG. 1A, it can be seen that the circuit board 178 of HDD 160 is fully submersed when the cooling jacket 100 is filled with cooling liquid. As such, the cooling jacket 100 is sized to at least encompass the circuit board 178 of HDD 160. Inlet nozzle 114 and inlet pipe 124 may be designed to be located so that inlet cooling liquid, which usually has a relatively lower temperature compared to the cooling liquid in other locations, is proximate to the SOC, which is generally the hottest part of HDD 160. Outlet nozzle 112 and outlet pipe 122 are located to facilitate flow of the cooling liquid across the surface of HDD 160 in need of cooling. Jacket 100 may include an interface adapter 140 having a male portion for connecting to the interface 190 of HDD 160 and a female portion for connecting to a JBOD chassis, for example. The interface adapter 140 is sealed against any leakage of cooling liquid.

The jacket 100 may be made in any suitable manner, such as by injection molding or thermoforming, for example. For use with hydrocarbon immersion cooling liquids, the jacket 100 may be made from materials such as polycarbonate (PC), polyoxymethylene (POM), polyamide (PA), HDPE (high-density polyethylene), and so forth. In such embodiments, the seal 130 may be made of elastomers such as fluoroelastomers including hexafluoropropylene (HFP), vinylidene fluoride (VDF), tetrafluoroethylene (TFE), fluorinated vinyl ether (FVE), and the like. For use with fluorinated cooling liquids, the jacket 100 may be made from materials such as polyvinyl chloride (PVC), silicone, thermoplastic elastomer resins such as styrene-ethylene-butadiene-styrene, thermoplastic olefin, thermoplastic polyurethane, polyether block amide, epoxy resin, and so forth. In such embodiments, the seal 130 may be made of silicone, natural rubber, polyurethane, polybutadiene, neoprene, and the like.

FIG. 1C indicates a perspective view showing the bottom and side of jacket 100. HDD 160 is inserted into the cooling jacket 100 so that the interface of HDD 160 is connected to the male portion of interface adapter 140, which resides in the interior of jacket 100. The female portion of adapter 140 is visible in FIG. 1C. Also shown is a bottom positioning feature 106 to help support HDD 160.

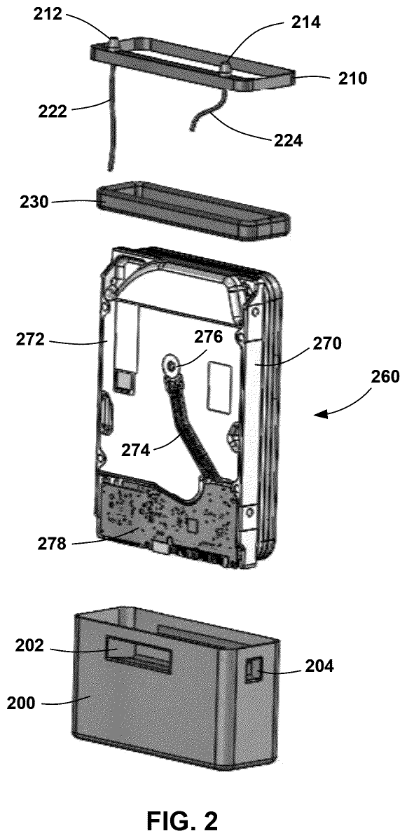

FIG. 2 shows a schematic exploded view of an HDD 260 and a disassembled cooling jacket assembly. HDD 260 has a base 270 including a back surface 272 on which are located a circuit board 278, spindle motor 276, and flex cable 274. Cooling jacket body 200 is sized to contain at least the portion of HDD 260 including circuit board 278. Jacket body 200 includes positioning features 202 and 204 for proper and stable positioning of the HDD 260. Jacket cover 210 includes an inlet nozzle 214 and outlet nozzle 212, which are respectively connected to inlet pipe 224 and outlet pipe 222. When HDD 260 is inserted into jacket body 200, the assembly is completed by installing jacket cover 210 and jacket seal 230 onto jacket body 200. A cooling liquid may be injected into the jacket 200 through the inlet nozzle 214, which is preferably done after the jacket assembly is assembled and the HDD 260 is fully inserted. It may also be possible to pre-fill the jacket with a small amount of cooling liquid prior to assembly.

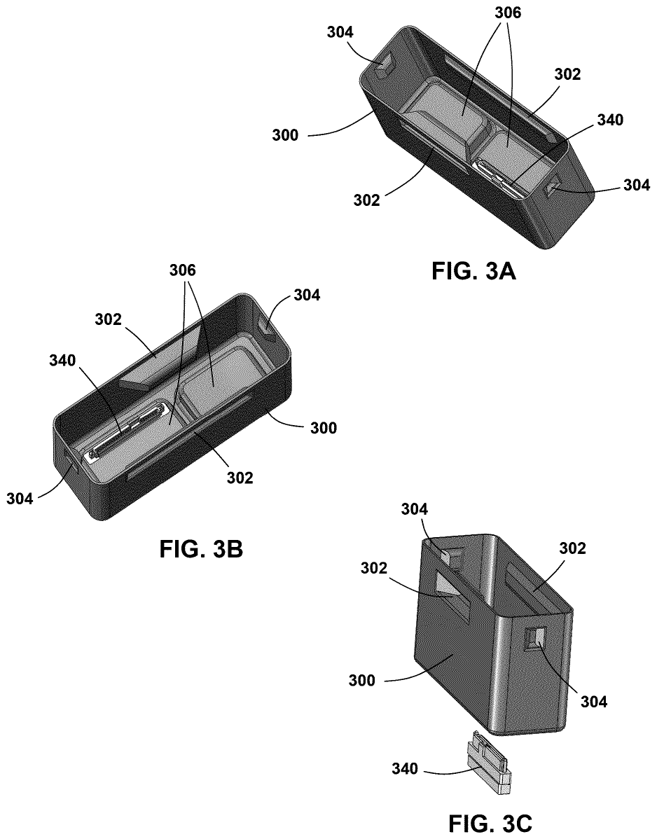

FIGS. 3A-3C schematically show different perspective views of a coolant jacket body 300 that includes an interface adaptor 340 to facilitate connecting of an electronic device such as an HDD with a chassis connector. By including an interface adaptor 340, the electronic device can be connected to the adaptor 340 when the cooling jacket is assembled around the electronic device, and then the electronic device and cooling jacket may be treated as a single assembly that is plugged into a connector array or chassis. In the case of an HDD, interface adaptor 340 may be a SATA or SAS adaptor that connects to the HDD on the interior of the jacket body 300 and that connects to a JBOD chassis on the outside of the jacket body 300. Jacket body 300 may also include side positioning features 304, front and back positioning features 302, and bottom positioning features 306, all of which assist in properly positioning the electronic device to be cooled during assembly as well as to maintain stability of the electronic device in the jacket.

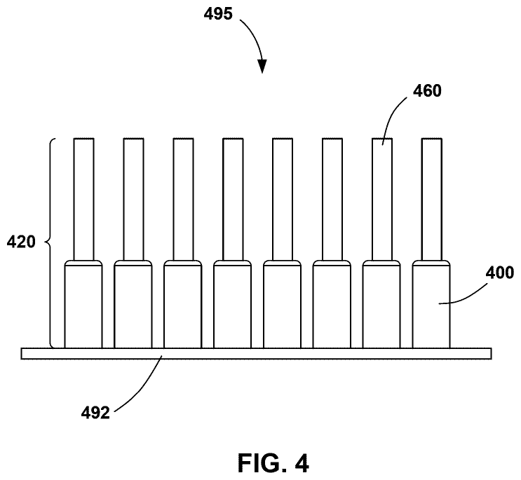

FIG. 4 schematically shows a device array 495 plugged into a connector array 492, for example of a storage server chassis. Device assemblies 420 are individually plugged into connector array 492. Each device assembly 420 includes an electronic device 460 that is inserted into a localized and targeted immersion cooling jacket 400 such that portions of device 460 that do not require immersion cooling are left exposed. In such an arrangement, design concepts currently used in air-cooling, for example as employed in many chassis and server racks, may continue to be leveraged, thereby reducing additional infrastructure costs while providing certain advantages of immersion cooling. It will be recognized that the localized and targeted immersion cooling methods and devices of the present disclosure may be applied in a variety of different environments in addition to JBOD servers, including network attached storage environments and surveillance system environments.

It should be understood that various aspects disclosed herein may be combined in different combinations than the combinations specifically presented in the description and accompanying drawings. It should also be understood that, depending on the example, certain acts or events of any of the processes or methods described herein may be performed in a different sequence, may be added, merged, or left out altogether (for example, all described acts or events may not be necessary to carry out the techniques). In addition, while certain aspects of this disclosure are described as being performed by a single module or unit for purposes of clarity, it should be understood that the techniques of this disclosure may be performed by a combination of units or modules.

All scientific and technical terms used herein have meanings commonly used in the art unless otherwise specified. The definitions provided herein are to facilitate understanding of certain terms used frequently herein and are not meant to limit the scope of the present disclosure.

As used herein, the term “configured to” may be used interchangeably with the terms “adapted to” or “structured to” unless the content of this disclosure clearly dictates otherwise.

As used herein, the term “or” refers to an inclusive definition, for example, to mean “and/or” unless its context of usage clearly dictates otherwise. The term “and/or” refers to one or all of the listed elements or a combination of at least two of the listed elements.

As used herein, the phrases “at least one of” and “one or more of” followed by a list of elements refers to one or more of any of the elements listed or any combination of one or more of the elements listed.

As used herein, the terms “coupled” or “connected” refer to at least two elements being attached to each other either directly or indirectly. An indirect coupling may include one or more other elements between the at least two elements being attached. Further, in one or more embodiments, one element “on” another element may be directly or indirectly on and may include intermediate components or layers therebetween. Either term may be modified by “operatively” and “operably,” which may be used interchangeably, to describe that the coupling or connection is configured to allow the components to interact to carry out described or otherwise known functionality.

The singular forms “a,” “an,” and “the” encompass embodiments having plural referents unless its context clearly dictates otherwise.

As used herein, “have,” “having,” “include,” “including,” “comprise,” “comprising” or the like are used in their open-ended sense, and generally mean “including, but not limited to.” It will be understood that “consisting essentially of,” “consisting of,”and the like are subsumed in “comprising,”and the like.

Reference to “one embodiment,” “an embodiment,” “certain embodiments,” or “some embodiments,” and so forth, means that a particular feature, configuration, composition, or characteristic described in connection with the embodiment is included in at least one embodiment of the disclosure. Thus, the appearances of such phrases in various places throughout are not necessarily referring to the same embodiment of the disclosure. Furthermore, the particular features, configurations, compositions, or characteristics may be combined in any suitable manner in one or more embodiments.

The words “preferred” and “preferably” refer to embodiments of the disclosure that may afford certain benefits, under certain circumstances. However, other embodiments may also be preferred, under the same or other circumstances. Furthermore, the recitation of one or more preferred embodiments does not imply that other embodiments are not useful and is not intended to exclude other embodiments from the scope of the disclosure.

What is claimed is:

1. A localized immersion cooling assembly comprising:
an electronic device including a heat source that produces heat primarily in or around a first portion of the electronic device, the electronic device inserted into a cooling jacket configured for insertion of a single electronic device, wherein the cooling jacket contains an immersion cooling fluid such that the immersion cooling fluid cools at least the first portion of the electronic device, and wherein a second portion of the electronic device remains outside of the cooling jacket.

2. The localized immersion cooling assembly of claim 1, wherein the electronic device is a hard disk drive.

3. The localized immersion cooling assembly of claim 1, wherein the cooling jacket includes one or more positioning features to position and stabilize the electronic device when inserted into the cooling jacket.

4. The localized immersion cooling assembly of claim 1, wherein the cooling jacket includes an interface adaptor configured to electrically connect an interface of the electronic device to a system connector located outside of the localized immersion cooling assembly.

5. The localized immersion cooling assembly of claim 1, wherein the cooling jacket includes a cover that comprises a fluid inlet nozzle and a fluid outlet nozzle.

6. The localized immersion cooling assembly of claim 5, further comprising a fluid inlet pipe connected to the fluid inlet nozzle, the fluid inlet pipe having an exit end positioned in an interior of the cooling jacket at a location at or near the heat source of the electronic device.

7. The localized immersion cooling assembly of claim 1, wherein the immersion cooling fluid comprises a hydrocarbon cooling liquid.

8. The localized immersion cooling assembly of claim 7, wherein the cooling jacket comprises polycarbonate (PC), polyoxymethylene (POM), polyamide (PA), or high-density polyethylene (HDPE).

9. The localized immersion cooling assembly of claim 1, wherein the immersion cooling fluid comprises a fluorinated cooling liquid.

10. The localized immersion cooling assembly of claim 9, wherein the cooling jacket comprises polyvinyl chloride (PVC), silicone, styrene-ethylene-butadiene-styrene, thermoplastic olefin, thermoplastic polyurethane, polyether block amide, or epoxy resin.

11. The localized immersion cooling assembly of claim 1, wherein the cooling jacket includes a seal configured to substantially enclose the cooling fluid within the cooling jacket when the electronic device is inserted into the cooling jacket.

12. The localized immersion cooling assembly of claim 11, wherein for use with hydrocarbon cooling liquids the seal comprises hexafluoropropylene (HFP), vinylidene fluoride (VDF), tetrafluoroethylene (TFE), or fluorinated vinyl ether (FVE).

13. The localized immersion cooling assembly of claim 11, wherein for use with fluorinated cooling liquids the seal comprises silicone, natural rubber, polyurethane, polybutadiene, or neoprene.

14. An immersion cooling jacket comprising:
a jacket body configured to contain an immersion cooling fluid and further configured for insertion of only a single electronic device through a top opening of the jacket body such that when the single electronic device is fully inserted into the jacket body a first portion of the single electronic device resides in the jacket body and a second portion of the single electronic device remains outside the jacket body;
a jacket cover configured to cover the top opening of the jacket body when the single electronic device is inserted into the jacket body; and
a jacket seal configured to form a seal between the jacket cover and the single electronic device.

15. The immersion cooling jacket of claim 14, further comprising an interface adaptor configured to electrically connect an interface of the single electronic device to a system connector located outside of the immersion cooling jacket.

16. The immersion cooling jacket of claim 15, wherein the single electronic device is a hard disk drive and the interface is a SAS interface or SATA interface.

17. The immersion cooling jacket of claim 14, wherein the immersion cooling fluid is a hydrocarbon cooling liquid or a fluorinated cooling liquid.

18. The immersion cooling jacket of claim 14, wherein the jacket body includes one or more positioning features configured to facilitate proper positioning of the single electronic device when the single electronic device is inserted into the jacket body.

19. The immersion cooling jacket of claim 14, wherein the jacket body is formed by injection molding or thermoforming.

20. A hard disk drive immersion cooling system comprising:
a JBOD chassis including a plurality of hard disk drive connectors; and
one or more localized immersion cooling assemblies, each localized immersion cooling assembly electrically connecting a hard disk drive to one of the plurality of hard disk drive connectors through an interface adaptor provided on an immersion cooling jacket that encloses an immersion cooling fluid around at least a portion of the hard disk drive.
